(19) United States
(12) Patent Application Publication
(10) Pub. No.: US 2024/0169600 A1
(43) Pub. Date: May 23, 2024

(54) VIRTUAL BOUNDARY ALLOCATION AND USER INTERACTION IN MULTI-USER ENVIRONMENT

(71) Applicant: INTERNATIONAL BUSINESS MACHINES CORPORATION, ARMONK, NY (US)

(72) Inventors: Michael Boone, Lutz, FL (US); Jeremy R. Fox, Georgetown, TX (US); Sarbajit K. Rakshit, Kolkata (IN); Tushar Agrawal, West Fargo, ND (US)

(21) Appl. No.: 18/058,302

(22) Filed: Nov. 23, 2022

(51) Int. Cl. G06T 11/00; G06F 3/01; G06F 30/20; G06Q 10/06; G06T 7/13; G06T 7/20; G06V 20/20

(52) U.S. Cl. CPC G06T 11/00; G06F 3/011; G06F 30/20; G06Q 10/0637; G06T 7/13; G06T 7/20; G06V 20/20; G06T 2207/30196; G06T 2210/21

(57) ABSTRACT

According to one embodiment, a method, computer system, and computer program product for creating virtual boundaries is provided. The present invention may include creating a virtual simulation of a physical space and of one or more workers and/or one or more machines and/or objects in the physical space; determining mobility boundaries required for performance of one or more activities; personalizing virtual boundaries for the one or more workers to perform the one or more activities based on the determined mobility boundaries; and displaying the virtual boundaries to the one or more workers depending on the one or more activities the worker is performing.

### BACKGROUND

The present invention relates, generally, to the field of computing, and more particularly to Industry 4.0 in combination with mixed reality.

Industry 4.0 is a modern computer technology that uses software to create computer-generated environments and enable digital manufacturing. Industry 4.0 overlays a virtual simulation on a real-time production line. Currently, Industry 4.0 can be used to optimize industrial processes by decreasing design and production costs, maintaining product quality, and reducing the time needed to go from product conception to product production. However, fully optimizing industrial processes likely also requires increasing the efficiency of the workers in the workplace. Therefore, optimizing workers' movements in the workplace can help achieve optimizing industrial processes. Thus, an improvement in Industry 4.0 has the potential to benefit the overall process optimization in the industrial workplace.

### SUMMARY

According to one embodiment, a method, computer system, and computer program product for creating virtual boundaries is provided. The present invention may include creating a virtual simulation of a physical space and of one or more workers and/or one or more machines and/or objects in the physical space; determining mobility boundaries required for performance of one or more activities; personalizing virtual boundaries for the one or more workers to perform the one or more activities based on the determined mobility boundaries; and displaying the virtual boundaries to the one or more workers depending on the one or more activities the worker is performing.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates an exemplary networked computer environment according to at least one embodiment;

FIG. 2 illustrates an exemplary application invention environment according to at least one embodiment;

FIG. 3 is an operational flowchart illustrating a virtual boundaries determination process according to at least one embodiment; and

FIG. 4 is a system diagram illustrating an exemplary program environment of an implementation of a virtual boundaries determination process according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

In an industrial workplace, workers perform various movements, such as hand gestures or walking around the workplace. Multiple workers performing movements in a workplace can lead to problems arising, thus, resulting in impaired physical mobility and limiting the workers from performing their activities effectively. For example, multiple workers may be individually moving around the workplace and collisions might arise between one or more workers if their paths intersect. Therefore, it may be likely that the process optimization of an industrial workplace is limited because of the impaired physical mobility between workers, therefore not allowing them to perform their activities effectively and efficiently. Additionally, health and safety reasons, such as COVID protocols mandating workers maintain a distance of 6 feet from one another, may dictate the mobility of workers in the workplace.

One way in which current methods attempt to address problems with maximizing the efficiency of workers' mobility in an industrial workplace is by having a user define a boundary relative to a physical geographic location based on the attributes of a physical space using an augmented reality (AR) device. Defined boundaries relative to a geographic location can be useful for a worker in a virtual space given the conditions of the workplace are static. However, several deficiencies exist with a user defining a boundary relative to a physical geographic location. One of the deficiencies with current methods is that when a user defines a boundary, the boundary is not dynamic. For example, a worker performing a virtual activity would have to manually adjust their boundary, thus slowing down the worker. Another deficiency of current methods is that predefining a boundary does not consider the boundaries of other workers. For example, if additional workers begin activities in the physical space while the worker is in the middle of an activity, the current boundaries of the worker may interfere with the workflow of the other workers, thus, increasing the likelihood of a potential collision and/or interference. Thus, an improvement in mixed reality has the potential to improve safety and worker efficiency and thus, benefit the user experience and the workplace.

The present invention has the capacity to improve mixed reality by dynamically creating and modifying individualized virtual boundaries for workers in a physical workplace. The present invention uses Industry 4.0 in combination with a mixed reality system to instruct the workers on how to complete their activities most efficiently by creating individualized virtual boundaries for the workers. This improvement in the creation of virtual boundaries in a mixed reality environment can be accomplished by implementing a system that identifies and creates a mixed reality simulated environment based on a physical workplace, personalizes individual virtual boundaries for the workers in the workplace to complete their activities, continuously tracks and updates the personalized individual virtual boundaries based on changes in the availability of physical space.

In some embodiments of the invention, the virtual boundaries determination program, herein referred to as “the program”, can render a mixed reality (MR) simulated environment. The MR simulated environment, herein referred to as “the MR environment”, may be a hybrid environment comprising both physical and virtual elements. The MR environment may comprise a hybrid physical/virtual world in which one or more workers may enter, see, move around in, interact with, etc. through the medium of a MR device. The workers in the MR environment may be able to see and/or interact with the same virtual objects and virtual elements and may interact with virtual representations of each other. The MR environment may comprise AR environments wherein generated images, sounds, haptic feedback, and other sensations are integrated into a real-world environment. The MR environment may comprise virtual reality (VR) environments that fully replace the physical environment with virtual elements, such that a worker experiencing a VR environment cannot see any objects or elements of the physical world; however, the VR environments are anchored to real-world locations, such that the movement of the workers, virtual objects, virtual environmental effects and elements all occur relative to the corresponding locations in the physical environment.

In some embodiments of the invention, the program can track the movements of the workers. IoT devices, such as cameras and/or sensors, can be used to detect what actions are being performed by the workers and the movement patterns of the workers. For example, wearable IoT devices or movement detection sensors may be used. The program can identify the types of activities that are performed in the workplace and both the machinery used and the movement pattern requirements for the performance of the activity. The program can identify the virtual boundaries required to perform the activities.

In some embodiments of the invention, the program can allocate appropriate physical space to each worker in the mixed reality environment. The program can allocate the physical space by creating personalized virtual boundaries based on the number of workers, the number of activities that are to be performed by the workers and learned data about the worker's movement patterns. The program can display the personalized virtual boundaries to the individual workers to assist the workers in performing their activities. The workers in the physical workplace can view the virtual boundaries displayed in the AR environment within their MR devices. The workers in remote locations can view the virtual boundaries displayed in the VR environment within their MR devices. The program can continuously track the movement of the workers and adjust one or more workers' personalized virtual boundaries. The program may identify potential collisions among the workers and/or with physical objects, may alert/warn the workers, and may adjust one or more workers' personalized virtual boundaries, based on learned information, to avoid the potential collisions. The program can identify if any worker completes an activity and how much space is freed up because of the completion of the activity. If the program determines that space has been freed up, the program can allocate some or all of the space to other workers depending on their need for additional space. Additionally, if any new worker joins the MR environment, the program can identify how the space may be reallocated to the workers. The program can identify if any optimization can be performed while assigning the virtual boundaries. The program can modify the personalized virtual boundaries based on the updated allocation of space to each worker. Also, the program can identify if a worker is taking up a larger portion of space than necessary to complete their activities. The program may propose why and how the worker may reduce the space they are using so that other workers could have greater virtual boundaries. The program can display the modified personalized virtual boundaries to the workers.

The program can enable collaboration in an Industry 4.0 environment among multiple workers. The program can identify how many workers are working from co-located places within the mixed reality system and the physical workplace. The program can personalize virtual boundaries for multiple workers working simultaneously in an industrial setting or an office setting to be able to perform their respective activities safely and properly with efficiency. The workers can be working in the same VR environment or different VR environments within the MR environment. The program can identify what activities in the workplace will be performed by workers. The program can identify how much space is available in the physical surrounding. The program can consider learned data about each activity and will be identifying how the physical space can be allocated. The workers may extend their virtual boundaries to include other workers for collaboration on an activity.

The program may use artificial intelligence in personalizing virtual boundaries by utilizing one or more machine learning models to ingest the data gathered by monitoring the worker's movements in the mixed reality environment. The machine learning models may be trained to predict the movements of the workers during the performance of their respective activities and thus, the space needed for the performance of their respective activities. The machine learning models may be trained on a knowledge corpus comprising learned information gathered from the IoT devices, such as the movement patterns of a worker during the performance of an activity.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation, or garbage collection, but this does not render the storage device as transitory because the data is not transitory while it is stored.

The following described exemplary embodiments provide a system, method, and program product to create personalized virtual boundaries for workers in a workplace using mixed reality by identifying workers, activities to be performed by the workers, and the layout of a workplace, rendering a mixed reality simulated environment of the workplace and the objects and workers in the workplace, determining space required to perform each activity in the workplace, personalizing virtual boundaries for each worker to perform their respective activities, displaying the personalized virtual boundaries to the workers depending on the activity the worker is performing, determining changes in the workplace's available space based on if new workers enter the workplace and/or workers finish their activities, modifying the personalized virtual boundaries based on changes in the workplace's available space, and displaying the modified personalized virtual boundaries to the workers.

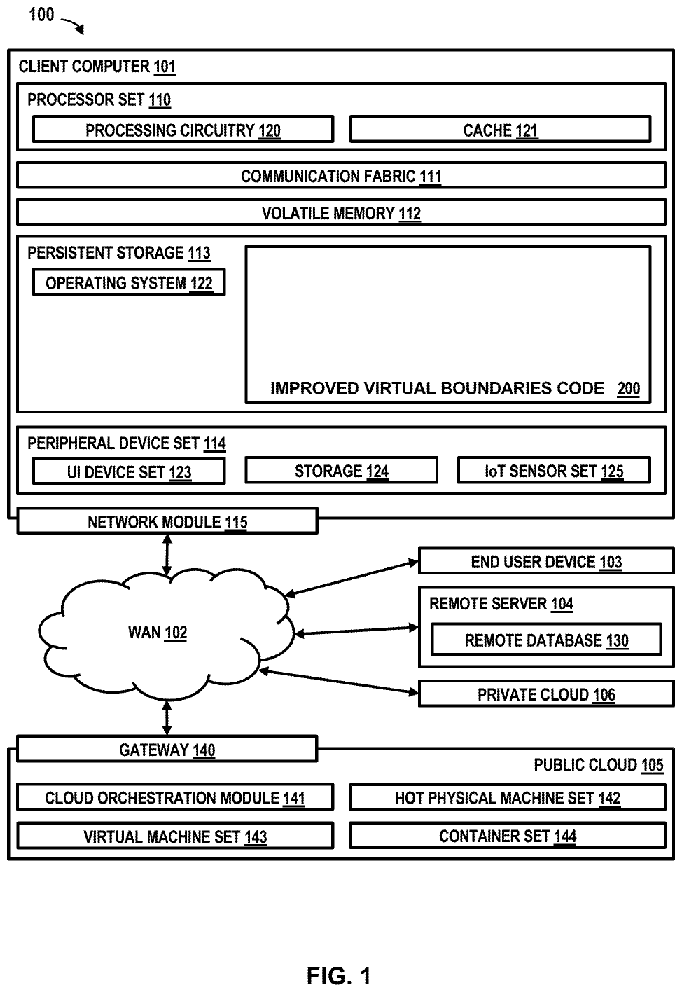

Referring to FIG. 1, an exemplary networked computer environment 100 is depicted, according to at least one embodiment. Computing environment 100 contains an example of an environment for the execution of at least some of the computer code involved in performing the inventive methods, such as improved virtual boundaries code 200. In addition to code block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and code block 200, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in code block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface type operating systems that employ a kernel. The code included in code block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

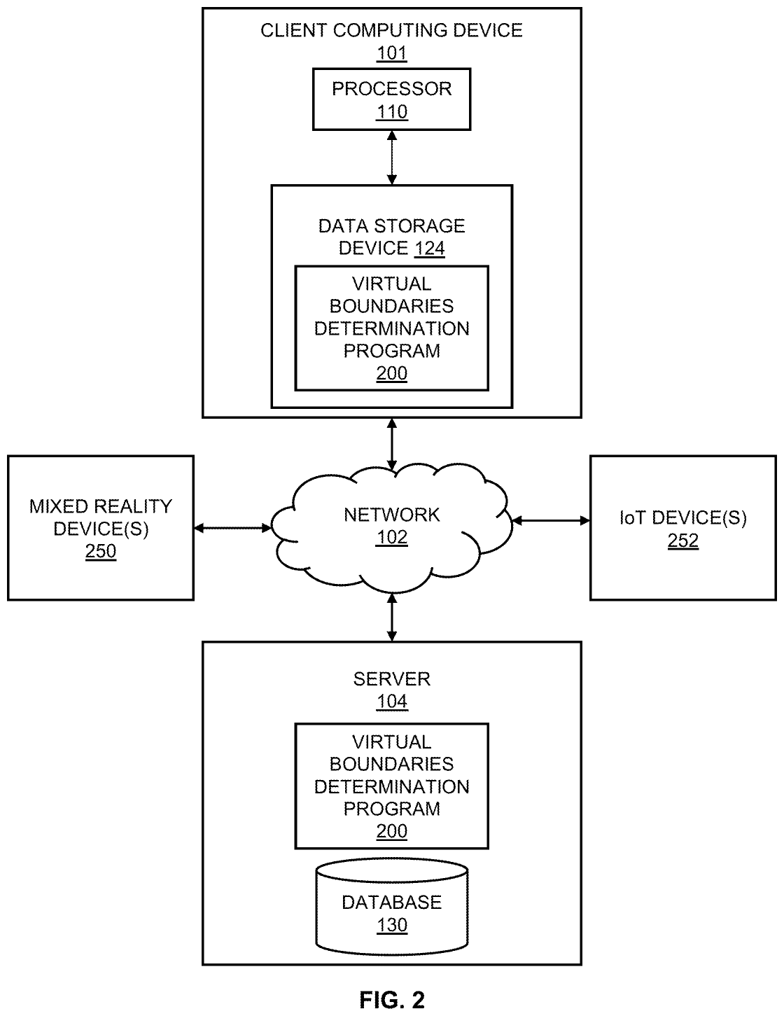

Referring to FIG. 2, an exemplary application environment is depicted, according to at least one embodiment. FIG. 2 may include client computing device 101 and a remote server 104 interconnected via a communication network 102. According to at least one implementation, FIG. 2 may include a plurality of client computing devices 101 and remote servers 104, of which only one of each is shown for illustrative brevity. It may be appreciated that FIG. 2 provides only an illustration of one implementation and does not imply any limitations with regard to the environments in which different embodiments may be implemented. Many modifications to the depicted environments may be made based on design and implementation requirements.

Client computing device 101 may include a processor 110 and a data storage device 124 that is enabled to host and run a virtual boundaries determination program 200 and communicate with the remote server 104 via the communication network 102, in accordance with one embodiment of the invention.

The remote server computer 104 may be a laptop computer, netbook computer, personal computer (PC), a desktop computer, or any programmable electronic device or any network of programmable electronic devices capable of hosting and running a virtual boundaries determination program 200 and a database 130 and communicating with the client computing device 101 via the communication network 102, in accordance with embodiments of the invention. The remote server 104 may also operate in a cloud computing service model, such as Software as a Service (SaaS), Platform as a Service (PaaS), or Infrastructure as a Service (IaaS). The remote server 104 may also be located in a cloud computing deployment model, such as a private cloud, community cloud, public cloud, or hybrid cloud.

The database 130 may be a digital repository capable of data storage and data retrieval. The database 130 can be present in the remote server 104 and/or any other location in the network 102. The database 130 can comprise a knowledge corpus. The knowledge corpus may comprise information related to the physical layout of a workplace, IoT devices 252 controlled using the MR GUI, workers' movement patterns, and the activities performed by the workers in the workplace. Additionally, the knowledge corpus may comprise each worker's profiles, which may comprise information related to the worker's performance of activities, such as the machines they use during each activity and their movement patterns during the performance of an activity. The knowledge corpus may be updated based on the continuous monitoring of the one or more workers.

Mixed reality (MR) device(s) 250 may be any device or combination of devices enabled to record-world information that the MR module 402 may overlay with computer-generated perceptual elements to create a MR environment. The MR device 250 can record the actions, position, movements, etc. of a worker, to track the worker's movement within and interactions with the MR environment. The MR device 250 can display a MR simulated environment to a worker and allow a worker to interact with the MR environment. Also, the MR headset 250 can comprise a head-mounted display (HMD). Additionally, the MR device 250 may be equipped with or comprise a number of sensors, such as a camera, microphone, and accelerometer, and these sensors may be equipped with or comprise a number of user interface devices such as touchscreens, speakers, etc. The MR device 250 can allow workers to control machines in the physical workplace from a remote location through the mixed reality system. The MR device 250 can allow workers to control machines in the physical workplace from a remote location by sending commands to the individual machines.

IoT device(s) 252 may be any device capable of tracking a worker's movements. The IoT device(s) 252 can comprise cameras, such as any device capable of recording visual images in the form of photographs, films, or video signals, such as a physical or virtual camera, and/or sensors, such as accelerometers, gyroscopes, magnetometers, proximity sensors, pressure sensors, etc.

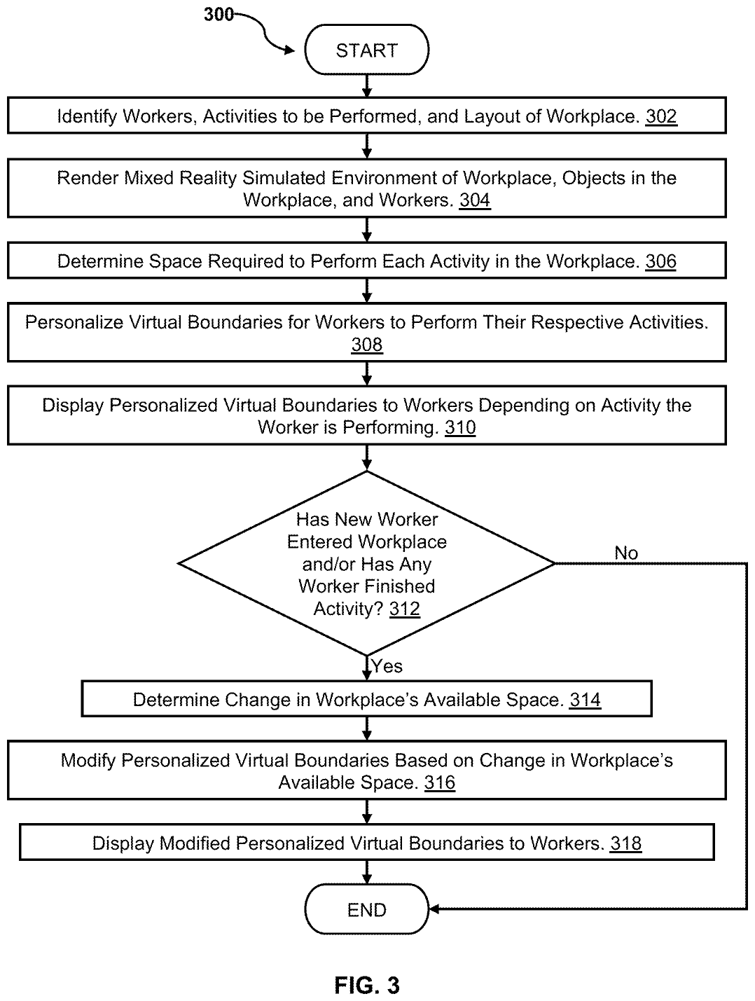

According to the present embodiment, the virtual boundaries determination program 200, herein referred to as “the program”, may be a program 200 capable of identifying and creating a mixed reality simulated environment based on a physical workplace, personalizing individual virtual boundaries for the workers in the workplace to complete their activities, continuously tracking and updating the personalized individual virtual boundaries based on changes in the availability of physical space. The virtual boundaries determination program 200 may be located on client computing device 101 or remote server 104 or on any other device located within network 102. Furthermore, virtual boundaries determination program 200 may be distributed in its operation over multiple devices, such as client computing device 101 and remote server 104. The virtual boundaries determination method is explained in further detail below with respect to FIG. 3.

Referring now to FIG. 3, an operational flowchart illustrating a virtual boundaries determination process 300 is depicted according to at least one embodiment. At 302, the program 200 identifies the workers, activities to be performed, and the layout of a physical workplace. The program 200 may identify one or more workers based on the amount of mixed reality devices 250 connected to the program 200. The workers may be co-located in the same physical and/or mixed reality simulated environment with each other. A mixed reality simulated environment can be a hybrid physical/digital version of the workplace. The program 200 may identify the activities the workers will be performing based on both the worker's profiles, and/or the workers' inputs to the graphical user interface (GUI). The program 200 may have a profile for each worker. A worker's profile may comprise information related to the worker's movement patterns and the activities performed by the worker in the workplace. A worker may select the activities the worker will be performing in the workplace on the mixed reality GUI. The knowledge corpus may comprise information relating to the requirements of each activity, such as what machines in the workplace are used and the movements of a worker during the performance of such activities. Additionally, the program 200 may identify the activities the workers are performing with IoT devices 252. The program 200 can determine the layout of the physical workplace using IoT devices 252, such as cameras and sensors, and/or by being fed structured data, such as a labeled map of the workplace.

At 304, the program 200 renders a mixed reality simulated environment of the physical workplace, the workers, the machinery and their connectors, and other physical objects in the workplace. A mixed reality simulated environment can be a digital representation of a workplace and can be updated dynamically in real time. The mixed reality simulated environment can be rendered by identifying the relative positions of the machinery and their connectors, such as conveyors and pipelines, other physical objects, and the workers, in the workplace. The program 200 may identify the relative positions using IoT devices 252, such as cameras and/or sensors, and can identify the positions using coordinate systems, such as cartesian coordinates, spherical polar coordinates, or cylindrical coordinates. The program 200 may display the mixed reality simulated environment to workers on their mixed reality devices 250.

At 306, the program 200 determines the space required to perform each activity in the workplace. The program 200 can determine the space required to perform each activity in the workplace based on learned information, such as general information about how an activity is performed in the workplace, for example, which machines are used during the performance of the activity or physical areas of the workplace that are visited during the performance of the activity, etc. The program 200 may use artificial intelligence (AI) in determining the space required to perform each activity in the workplace by utilizing a machine learning model to ingest the data gathered by the MR device 250 and the IoT devices 252 and can relay the data to a processor set 110. The machine learning model may be trained on a knowledge corpus comprising learned information gathered from structured data and/or from the MR devices 250 and the IoT devices 252. The machine learning model may be trained to predict the movements of the workers during the performance of the activities based on the machines used in the workplace and the areas visited in the workplace, and thus, the space needed for the performance of the activities.

At 308, the program 200 personalizes virtual boundaries for the workers to perform their respective activities. Once the program 200 determines the space required to generally perform each activity in the workplace, the program 200 can allocate the available space to each worker in a manner tailored to each user, by considering specific learned information about each worker and how the worker performs their respective activities. A machine learning model can be trained on a knowledge corpus comprising learned information gathered from structured data and/or from the MR devices 250 and the IoT devices 252 about the movement paths of an individual worker, such as the workers' unique movements while performing their activities over time. The program 200 can continuously track the movements of the workers using IoT devices 252, such as cameras and sensors, for example, a wearable motion sensor. The IoT devices 252 can produce data about different aspects of the worker's movement patterns when performing an activity in the workplace, such as if a worker might require more arm space because they stretch their arms out in a frequent manner, and what path a worker takes to get from a certain machine to another machine used for the same activity, etc. Employment of the machine learning model can comprise predicting the potential movements of each worker during an activity based on the worker's movements over time while performing an activity, the number of other workers in the mixed reality simulated environment, the number of workers in the physical environment, the other activities being performed in the workplace, and/or other similar factors. For example, if a worker is sitting and working at a machine, the predicted physical movements of the worker may comprise predicted arm movements. However, if the performance of an activity comprises the worker walking from one workspace to another, the predicted physical movements of the worker may comprise predicting the worker's movement based on the paths the worker has previously taken while working on the activity. The program 200 can personalize virtual boundaries for each worker to allow them to perform their activities based on their predicted movements during the performance of each of their respective activities.

The program 200 can continuously track the workers' movement and notify the workers if a potential collision between workers and/or a worker and a physical object is detected. The program 200 may notify the workers with a visual alert displayed on the MR device 250 and an audio alert triggered on the MR device 250, such as a bell sound. The program 200 may detect a potential collision between workers based on if a worker infringes and/or enters another worker's virtual boundaries. The program 200 may detect a potential collision between a worker and a physical object if a worker gets closer than a certain threshold, such as 5 cm, to a physical object. The program 200 may adjust the personalized virtual boundaries of one or more workers to attempt to subside the potential of the collision.

In some embodiments of the invention, the program 200 can determine if a worker is taking up a larger portion of space than necessary to complete their activities. The program 200 may determine if a worker is taking up a larger portion of space than necessary by detecting that one or more workers have positioned themselves outside of their personalized virtual boundaries. The program 200 can advise the worker on how to reduce the space they are using so that other workers can have greater virtual boundaries, for example, suggest and display an alternative path for a worker to take to get one machine to another machine.

In some embodiments of the invention, the workers may extend their virtual boundaries to include other workers for collaboration on an activity. The workers may choose to collaborate on an activity and select an option to collaborate with one or more workers on the MR device 250. The program 200 may combine the virtual boundaries of the workers who are collaborating during the performance of the collaborated activity.

At 310, the program 200 displays the personalized virtual boundaries to the workers depending on the activity the worker is performing. A worker may select what activity they are performing on the mixed reality GUI and/or the program 200 may determine what activity the worker is performing using the IoT devices 252, specifically object recognition. The personalized virtual boundaries can be shown to the workers in the mixed reality simulated environment on the workers' mixed reality devices 250. The personalized virtual boundaries can be displayed using virtual colored walls, like a red see-through virtual wall, and/or mapped lines on the MR device 250.

Then, at 312, the program 200 detects if one or more new workers have entered the workplace, either physically and/or virtually, and/or if any worker has concluded their activities. According to one implementation, if the program 200 detects that one or more new workers have entered the workplace and/or if any worker has concluded their activities (step 312, “YES” branch), the program 200 may continue to step 314 to determine the changes in the workplace's available space. If the program 200 detects that one or more new workers have not entered the workplace and no worker has concluded their activities (step 312, “NO” branch), the program 200 may continue monitoring the workers. A new worker may be any worker who joins the MR environment after the initial allocation of personalized virtual boundaries to workers. The program 200 may detect if one or more new workers have entered the MR simulated environment based on additional mixed reality devices 250 connecting to the program 200. The program 200 may detect if any worker has concluded their activities based on a worker's mixed reality device 250 disconnecting from the program 200 and/or the program 200 detecting, using IoT devices 252, that a worker is no longer moving in a certain portion of their allocated physical space, and/or no longer using a particular machine in the workplace.

At 314, the program 200 can determine changes in the workplace's available space in the same ways as detailed in steps 302 through 306, differences comprising the inclusion of new workers, the exclusion of workers, and/or activities, in the program's 200 identification of workers, activities to be performed, and layout of the workplace in step 302.

At 316, the program 200 modifies the personalized virtual boundaries of each worker based on the determined changes in the workplace's available space. The program 200 can determine the modified personalized virtual boundaries in the same way as detailed in step 308, differences comprising the inclusion of new workers, the exclusion of workers, and/or activities, in the program's 200 identification of workers, activities to be performed, and layout of the workplace in the program's 200 personalization of the virtual boundaries for the workers to perform their respective activities.

At 318, the program 200 displays the modified personalized virtual boundaries to the workers. The modified personalized virtual boundaries may be displayed to the workers in the same way as detailed in step 310. The modified personalized virtual boundaries can be displayed using the same color virtual walls as the worker's previously determined personalized virtual boundaries, different color virtual walls, and/or mapped lines on the MR device 250.

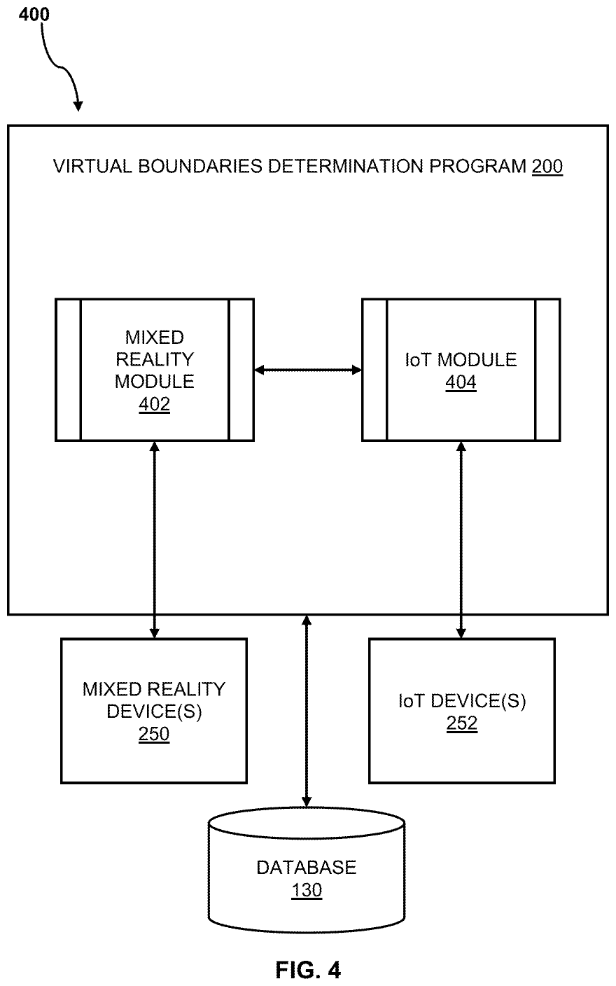

Referring now to FIG. 4, a system diagram illustrating an exemplary program environment 400 of an implementation of a virtual boundaries determination process 300 is depicted according to at least one embodiment. Here, the program 200 comprises a mixed reality module 402 and an IoT module 404. The exemplary program environment 400 details the interactions between the mixed reality module 402 and the IoT module 404. Additionally, the exemplary program environment 400 details the interactions between the mixed reality module 402 and the mixed reality device 250, the IoT module 404 and the IoT device(s) 252, and the program 200 and the database 130.

The mixed reality module 402 may be used to display the mixed reality simulated environment and the personalized virtual boundaries. The IoT module 404 may be used to communicate with the IoT device(s) 252.

It may be appreciated that FIGS. 2 through 4 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A processor-implemented method for creating virtual boundaries, the method comprising:
creating a virtual simulation of a physical space and of one or more workers and/or one or more machines and/or objects in the physical space;
determining mobility boundaries required for performance of one or more activities;
personalizing virtual boundaries for the one or more workers to perform the one or more activities based on the determined mobility boundaries; and
displaying the virtual boundaries to the one or more workers depending on the one or more activities the worker is performing.

2. The method of claim 1, further comprising:
detecting that one or more new workers have entered the space, physically and/or virtually; and/or
detecting that the one or more workers have finished the one or more activities.

3. The method of claim 2, further comprising:
determining if the physical space has any availability changes;
modifying the personalized virtual boundaries based on the availability changes of the physical space; and
displaying the modified personalized virtual boundaries to the one or more workers depending on the one or more activities the worker is performing.

4. The method of claim 1, further comprising:
tracking movements of the one or more workers continuously using at least one IoT device in addition to a mixed reality device.

5. The method of claim 1, further comprising:
notifying the one or more workers of a potential collision between the one or more workers with each other and/or a physical object.

6. The method of claim 1, wherein the personalization of virtual boundaries for the one or more workers to perform the one or more activities based on the determined mobility boundaries is performed by one or more machine learning models trained on a knowledge corpus.

7. The method of claim 1, wherein the one or more activities the worker is performing is determined using object recognition and/or predetermined data.

8. A computer system for creating virtual boundaries, the computer system comprising:
one or more processors, one or more computer-readable memories, one or more computer-readable tangible storage medium, and program instructions stored on at least one of the one or more tangible storage medium for execution by at least one of the one or more processors via at least one of the one or more memories, wherein the computer system is capable of performing a method comprising:
creating a virtual simulation of a physical space and of one or more workers and/or one or more machines and/or objects in the physical space;
determining mobility boundaries required for performance of one or more activities;
personalizing virtual boundaries for the one or more workers to perform the one or more activities based on the determined mobility boundaries; and
displaying the virtual boundaries to the one or more workers depending on the one or more activities the worker is performing.

9. The computer system of claim 8, further comprising:
detecting that one or more new workers have entered the space, physically and/or virtually; and/or
detecting that the one or more workers have finished the one or more activities.

10. The computer system of claim 9, further comprising:
determining if the physical space has any availability changes;
modifying the personalized virtual boundaries based on the availability changes of the physical space; and
displaying the modified personalized virtual boundaries to the one or more workers depending on the one or more activities the worker is performing.

11. The computer system of claim 8, further comprising:
tracking movements of the one or more workers continuously using at least one IoT device in addition to a mixed reality device.

12. The computer system of claim 8, further comprising:
notifying the one or more workers of a potential collision between the one or more workers with each other and/or a physical object.

13. The computer system of claim 8, wherein the personalization of virtual boundaries for the one or more workers to perform the one or more activities based on the determined mobility boundaries is performed by one or more machine learning models trained on a knowledge corpus.

14. The computer system of claim 8, wherein the one or more activities the worker is performing is determined using object recognition and/or predetermined data.

15. A computer program product for creating virtual boundaries, the computer program product comprising:
one or more computer-readable tangible storage medium and program instructions stored on at least one of the one or more tangible storage medium, the program instructions executable by a processor to cause the processor to perform a method comprising:
creating a virtual simulation of a physical space and of one or more workers and/or one or more machines and/or objects in the physical space;
determining mobility boundaries required for performance of one or more activities;
personalizing virtual boundaries for the one or more workers to perform the one or more activities based on the determined mobility boundaries; and
displaying the virtual boundaries to the one or more workers depending on the one or more activities the worker is performing.

16. The computer program product of claim 15, further comprising:
detecting that one or more new workers have entered the space, physically and/or virtually; and/or
detecting that the one or more workers have finished the one or more activities.

17. The computer program product of claim 16, further comprising:
determining if the physical space has any availability changes;
modifying the personalized virtual boundaries based on the availability changes of the physical space; and
displaying the modified personalized virtual boundaries to the one or more workers depending on the one or more activities the worker is performing.

18. The computer program product of claim 15, further comprising:
tracking movements of the one or more workers continuously using at least one IoT device in addition to a mixed reality device.

19. The computer program product of claim 15, further comprising:
notifying the one or more workers of a potential collision between the one or more workers with each other and/or a physical object.

20. The computer program product of claim 15, wherein the personalization of virtual boundaries for the one or more workers to perform the one or more activities based on the determined mobility boundaries is performed by one or more machine learning models trained on a knowledge corpus.
